(19) United States
(12) Patent Application Publication
(10) Pub. No.: US 2026/0271210 A1
(43) Pub. Date: Sep. 10, 2026

(54) ELECTRONIC DEVICE

(71) Applicant: SANYO DENKI CO., LTD., Tokyo (JP)

(72) Inventors: Takao Oshimori, Tokyo (JP); Mitsuru Takasugi, Tokyo (JP); Kazuki Fujita, Tokyo (JP); Yukiya Hashimoto, Tokyo (JP)

(21) Appl. No.: 19/557,851

(22) Filed: Mar. 5, 2026

(30) Foreign Application Priority Data
Mar. 7, 2025 (JP) 2025-036210

(51) Int. Cl. H05K 7/14; H02M 3/00

(52) U.S. Cl. CPC H05K 7/1432; H02M 3/003

(57) ABSTRACT

An electronic device includes a case, a board provided in the case, and a connector mounted on the board using an attachment pin. The case has a first portion and a second portion. The first portion faces the attachment pin and is made of resin. The second portion is different from the first portion and is made of metal.

### CROSS-REFERENCE TO RELATED APPLICATIONS

This application is based on and claims priority under 35 USC 119 from Japanese Patent Application No. 2025-036210 filed on March 7, 2025, the entire content of which is incorporated herein by reference.

### TECHNICAL FIELD

The present disclosure relates to an electronic device.

### BACKGROUND ART

JP2005-327643A discloses an electronic device including a printed wiring board on which an electronic component and a connector are mounted, and a case that accommodates the printed wiring board.

In an electronic device in which a connector is mounted on a board, in a case where a case is made of metal, it is necessary to secure a large separation distance between an attachment pin of the connector and the metal case so as to prevent an electrical short circuit between the attachment pin and the metal case. However, if a large separation distance is secured between the attachment pin and the metal case, the overall size of the electronic device increases.

### SUMMARY OF INVENTION

Aspect of non-limiting embodiments of the present disclosure relates to provide an electronic device that can be reduced in size with a simple configuration.

Aspects of certain non-limiting embodiments of the present disclosure address the features discussed above and/or other features not described above. However, aspects of the non-limiting embodiments are not required to address the above features, and aspects of the non-limiting embodiments of the present disclosure may not address features described above.

According to an aspect of the present disclosure, there is provided an electronic device including:

a case;

a board provided in the case; and

a connector mounted on the board using an attachment pin,

in which the case has a first portion and a second portion, the first portion facing the attachment pin and being made of resin, the second portion being different from the first portion and being made of metal.

### BRIEF DESCRIPTION OF DRAWINGS

Exemplary embodiment(s) of the present invention will be described in detail based on the following figures, wherein:

FIG. 1 is a perspective view showing an electronic device according to an embodiment of the present disclosure;

FIG. 2 is a cross-sectional view taken along line II-II in FIG. 1;

FIG. 3 is a perspective view of the electronic device according to the present disclosure seen from below;

FIG. 4 is a cross-sectional view showing an electronic device according to another embodiment of the present disclosure.

### DESCRIPTION OF EMBODIMENTS

### Details of Embodiment of Present Disclosure

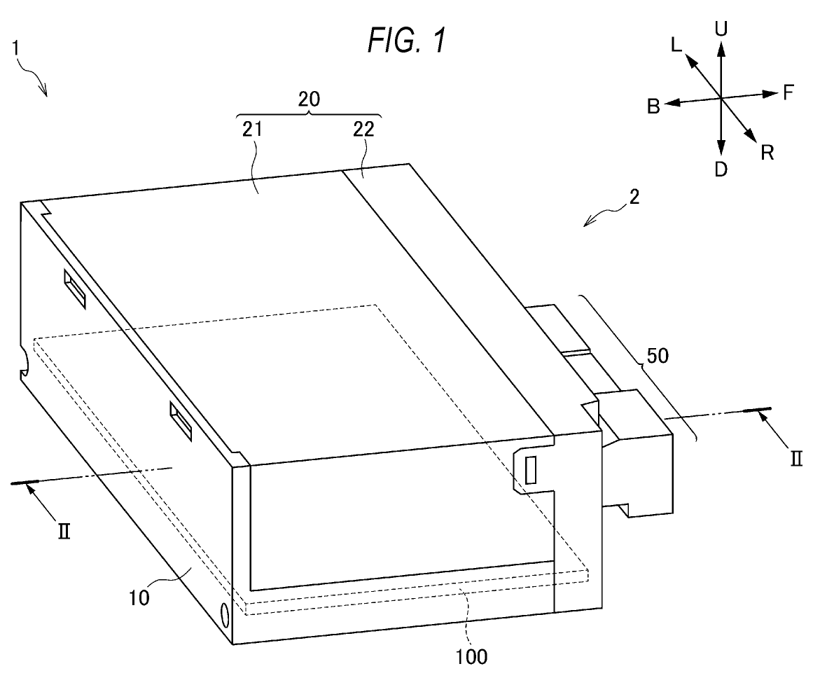

A specific example of an electronic device according to an embodiment of the present disclosure will be described below with reference to the drawings. Note that, the present disclosure is not limited to these examples, but is indicated by claims, and is intended to include all modifications within the meaning and scope equivalent to claims. Note that members having the same reference numerals as members already described in the description of the embodiment will not be described for convenience of description. The dimensions of each member illustrated in the drawings may be different from the actual dimensions of each member for convenience of description. Note that, U, D, R, L, F and B illustrated in FIG. 1 and the like indicate directions in an electronic device 1, where U is an upper direction, D is a lower direction, R is a right direction, L is a left direction, F is a front direction, and B is a rear direction.

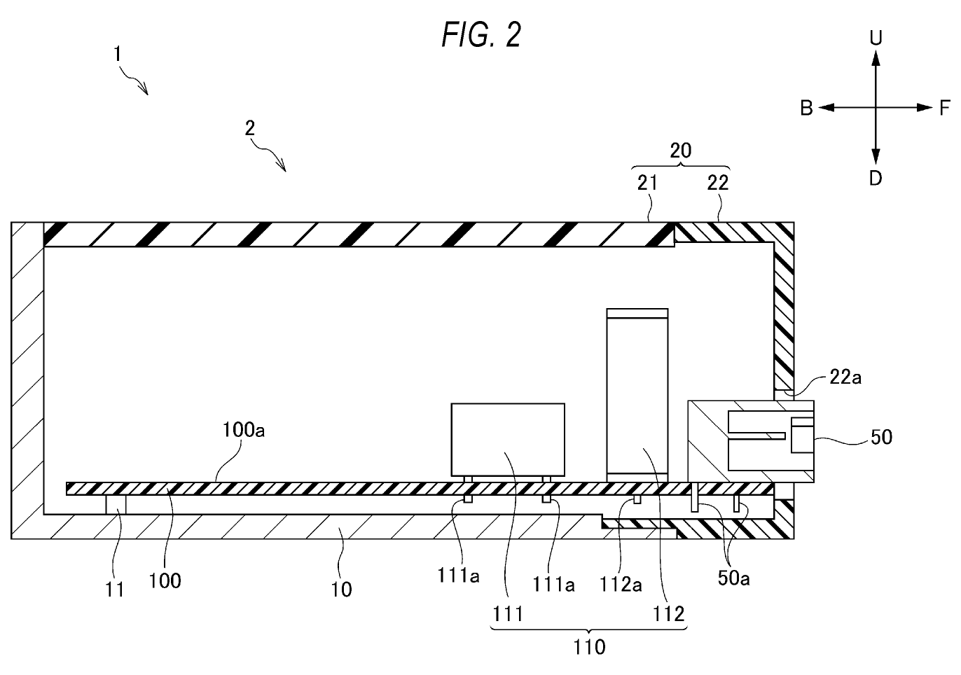

The electronic device 1 according to the present embodiment will be described in detail with reference to FIGS. 1 and 2. FIG. 1 is a perspective view showing the electronic device 1 according to an embodiment of the present disclosure. FIG. 2 is a cross-sectional view taken along line II-II in FIG. 1. The electronic device 1 according to the embodiment of the present disclosure is, for example, a servo amplifier.

As illustrated in FIGS. 1 and 2, the electronic device 1 includes a rectangular case 2, a connector 50, a board 100, and an electronic component 110. Note that, in FIG. 1, the board 100 cannot be visually recognized and is therefore indicated by a broken line. In FIG. 1, illustration of the electronic component 110 is omitted.

The case 2 is a box-shaped member capable of accommodating the board 100, the electronic component 110, and at least a part of the connector 50. The case 2 includes a metal case 10 made of metal and a resin case 20 made of resin. The case 2 is formed by fitting and fixing the metal case 10 and the resin case 20 to each other. Therefore, the electronic device 1 according to the present embodiment includes a surface made of metal and a surface made of resin provided, as an outer peripheral surface and an inner peripheral surface. The metal case 10 and the resin case 20 may be fixed by screwing or the like.

The metal case 10 has a substantially L shape when viewed from a left-right direction, and is a member forming a lower surface and a rear surface of the case 2. The metal case 10 has a board attachment portion 11 that protrudes upward from a lower surface on an inner peripheral side to support the board 100. Although not shown in FIG. 2, the metal case 10 includes a plurality of board attachment portions 11.

The resin case 20 is a member forming an upper surface, a front surface, and a part of left and right side surfaces of the case 2. The resin case 20 includes a side surface member 21 forming the upper surface and the part of left and right side surfaces of the case 2, and a cover member 22 forming the front surface of the case 2. The side surface member 21 is fixed to the metal case 10. The cover member 22 is fitted and fixed to the side surface member 21. The cover member 22 has an opening 22a for exposing the connector 50.

As shown in FIG. 2, the board 100 and the electronic component 110 are provided inside the case 2. The board 100 is a printed circuit board made of resin with a pattern formed on its surface. The board 100 has a mounting surface 100a, and the electronic component 110 and the connector 50 are attached to the mounting surface 100a. The board 100 is fixed to the inner peripheral surface of the case 2. In the present embodiment, the board 100 is fixed to the board attachment portion 11 provided in the metal case 10. For example, the board 100 is fixed by inserting a screw penetrating the board 100 into the board attachment portion 11 having a screw hole.

The electronic component 110 includes a first electronic component 111 and a second electronic component 112. The first electronic component 111 is configured to generate a larger amount of heat than the second electronic component 112. The first electronic component 111 is, for example, a power conversion unit configured to convert an input voltage into a desired output voltage. The power conversion unit refers to an electronic component including, for example, a switching element such as an insulated gate bipolar transistor (IGBT), a capacitor, a transformer, and a diode. The second electronic component 112 is configured to generate a smaller amount of heat than the first electronic component 111. Second electronic component 112 is, for example, a resistor. In the following description, the first electronic component 111 and the second electronic component 112 may be collectively referred to as an "electronic component 110".

The connector 50 is a member that is provided to protrude from the inside to the outside of the case 2 and to which an electric wire or the like can be connected from the outside. The electronic device 1 includes a plurality of connectors 50. The connectors 50 are electrically connected to the board 100.

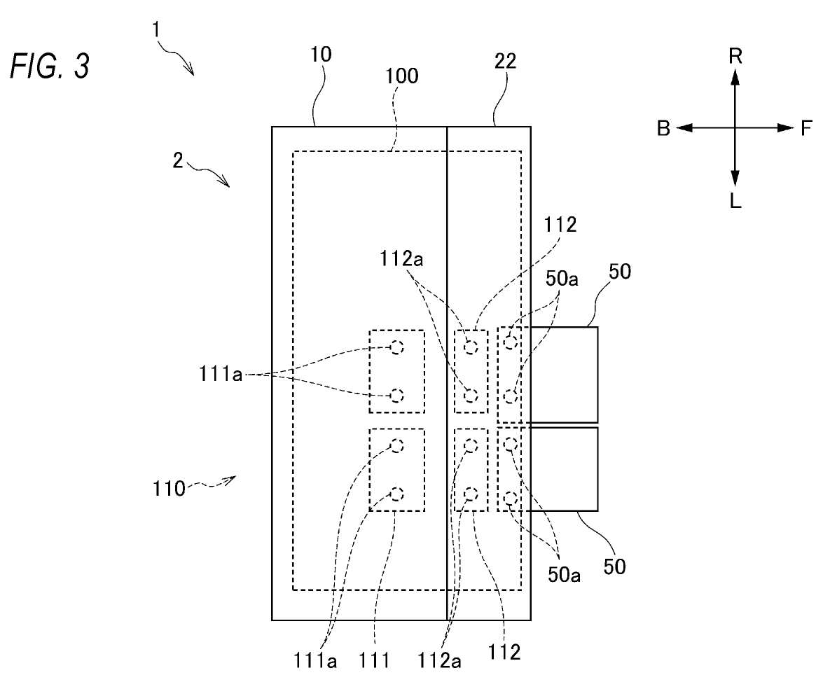

Next, the manner in which the electronic component 110 and the connectors 50 are attached to the board 100 will be described in detail with reference to FIGS. 2 and 3. FIG. 3 is a perspective view of the electronic device 1 according to the present disclosure seen from below. As shown in FIGS. 2 and 3, the connector 50 is attached to the board 100 using an attachment pin 50a. Similarly to the connector 50, the first electronic component 111 is attached to the board 100 using an attachment pin 111a. The second electronic component 112 is attached to the board 100 using an attachment pin 112a. Here, the "attachment pin" refers to a terminal pin for electrically connecting the connector 50 and the electronic component 110 to the board 100. Note that, the connector 50 and the electronic component 110 may include fixing pins for fixing the connector 50 and the electronic component 110 to the board 100.

As shown in FIGS. 2 and 3, the attachment pin 50a of the connector 50 is provided at a position facing the cover member 22 in the resin case 20. That is, the case 2 is made of resin at a position facing the position where the attachment pin 50a of the connector 50 is attached.

In the electronic device 1, if the case 2 is made of metal, there is a risk of an electrical short circuit between the electronic component 110 attached inside the electronic device 1 and the case 2. In particular, the attachment pin 50a requires mechanical strength to be attached, and therefore it is necessary to fix the attachment pin 50a to the board with a sufficient amount of solder. However, in order to apply a sufficient amount of solder to the attachment pin 50a, it is necessary to lengthen the attachment pin 50a, and thus the length of the attachment pin 50a protruding from a back surface of the board becomes long in the long attachment pin 50a that requires mechanical strength. Therefore, it is necessary to secure a large separation distance between the metal case 10 and the long attachment pin 50a, which requires mechanical strength for attachment, in order to prevent an electrical short circuit. On the other hand, if a large separation distance is secured between the metal case 10 and the attachment pin 50a, there is a problem that the case 2 becomes large.

According to the configuration of the present disclosure, a portion of the case 2 that faces the attachment pin 50a of the connector 50 is made of resin. Accordingly, even if the case 2 and the attachment pin 50a are close to each other, it is possible to prevent an electrical short circuit. Further, since the separation distance between the case 2 and the attachment pin 50a can be reduced, the entire electronic device 1 can be reduced in size.

Note that, portions of the case 2 other than the portion that faces the attachment pin 50a of the connector 50 may be made of metal. That is, it is sufficient that at least the portion of the case 2 that faces the attachment pin 50a of the connector 50 is made of resin.

The electronic device 1 according to the present disclosure is particularly suitable in a case where the board 100 is mounted with the first electronic component 111 that is at least a part of the electronic component 110 and is a power conversion unit. In a case where the power conversion unit is provided in the electronic device 1, the inside of the case 2 is required to be electromagnetically shielded. In this case, the case 2 is necessarily made of metal for electromagnetic shielding. According to the electronic device 1 of the present disclosure, even in the electronic device 1 that includes a power conversion unit that requires the use of the metal case 10, an electrical short circuit between the connector 50 and the case 2 can be prevented. Further, according to the electronic device 1 of the present disclosure, the entire electronic device 1 can be reduced in size. Note that, when the power conversion unit is provided in the electronic device 1, the case 2 may be made of metal to an extent that enables electromagnetic shielding. That is, even if the power conversion unit is provided in the electronic device 1, the entire case 2 does not need to be made of metal.

In the electronic device 1 according to the present disclosure, a back surface of the mounting surface 100a of the board 100 is disposed to face the case 2. In other words, in the normal direction of the mounting surface 100a of the board 100, a distance between the back surface of the mounting surface 100a of the board 100 and the case 2 is shorter than a distance between the mounting surface 100a of the board 100 and the case 2. According to the above configuration, the board 100 and the case 2 can be brought closer to each other. Accordingly, the internal space of the case 2 can be effectively used, which not only increases the degree of freedom in designing the layout of the components inside the case 2 but also allows the overall size of the electronic device 1 to be reduced.

In the electronic device 1 according to the present disclosure, the metal case 10 may function as a heat sink that efficiently discharges heat generated from the electronic component 110 to the outside. According to the above configuration, the heat inside the electronic device 1 can be efficiently discharged to the outside. Note that, the metal case 10 may be provided with heat dissipation fins or irregularities for heat dissipation on the outer peripheral surface so that the heat inside the case 2 can be more efficiently discharged. Further, the metal case 10 and the resin case 20 may be provided with through holes that connect the inside and the outside of the case 2 in order to efficiently discharge the heat from inside the case 2 to the outside.

In the electronic device 1 according to the present disclosure, the first electronic component 111, which generates a larger amount of heat than the second electronic component 112, may be provided at a position facing the metal case 10.

In the above-described embodiment, the amount of heat generated by the first electronic component 111 is greater than that of the second electronic component 112. The first electronic component 111 is attached to the board 100 at a position facing the metal case 10. According to the above configuration, the heat generated by the first electronic component 111 can be efficiently dissipated to the outside via the metal case 10.

In the electronic device 1 according to the present disclosure, the first electronic component 111 and the second electronic component 112 may not be attached by attachment pins penetrating the board 100. For example, the first electronic component 111 and the second electronic component 112 may be attached to a surface of board 100 by soldering.

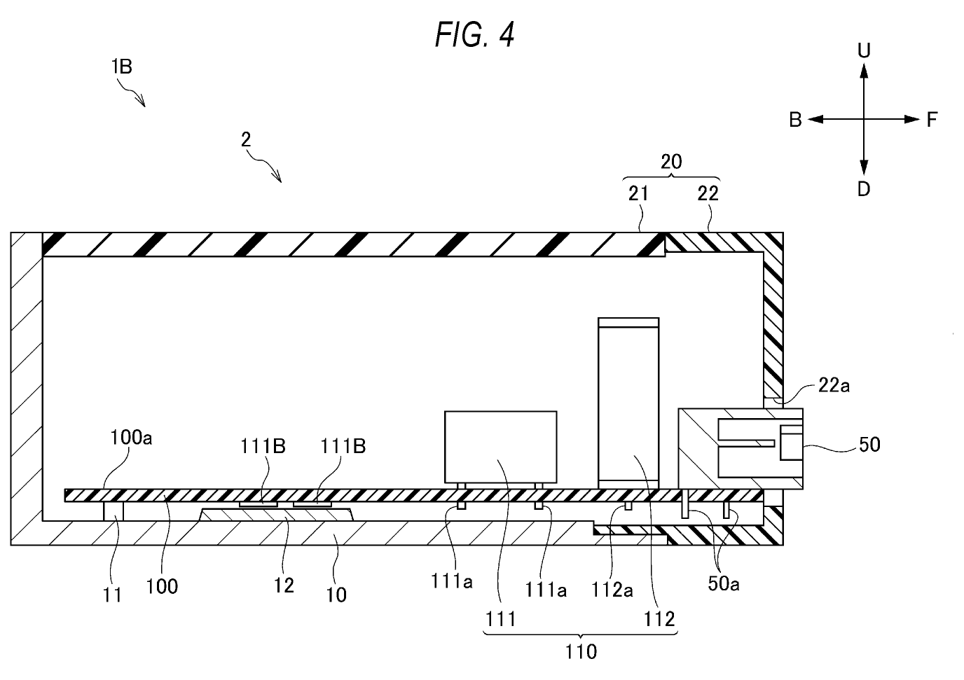

FIG. 4 shows an electronic device 1B according to another embodiment of the present disclosure. As illustrated in FIG. 4, in the electronic device 1B according to the present disclosure, at least a part (first electronic component 111B) of the first electronic component 111 that generates a larger amount of heat than the second electronic component 112 is attached to the back surface of the mounting surface 100a of the board 100. According to the above configuration, since a separation distance between the first electronic component 111B and the metal case 10 can be shortened, the heat generated by the first electronic component 111B can be efficiently dissipated. The first electronic component 111B is preferably a component that generates a particularly large amount of heat among the first electronic components 111. According to this configuration, since the component having a larger amount of heat generation than other components can be brought closer to the metal case 10, heat dissipation efficiency can be improved. Further, the first electronic component 111Bis preferably a component having a short height dimension among the first electronic components 111. According to this configuration, even if the first electronic component 111B is attached to the back surface of the mounting surface 100a, a separation distance between the back surface of the mounting surface 100a and the case 2 in the normal direction of the board 100 can be shortened. Accordingly, the internal space of the case 2 can be effectively used, which not only increases the degree of freedom in designing the layout of the components inside the case 2 but also allows the overall size of the electronic device 1 to be reduced.

As shown in FIG. 4, at a position facing the first electronic component 111B, the metal case 10 has a protruding portion 12 that protrudes upward from the lower surface on the inner peripheral side. According to the above configuration, since a separation distance between the first electronic component 111B and the metal case 10 can be shortened, the heat generated from the first electronic component 111B can be efficiently dissipated. Note that, the protruding portion 12 may be provided to be in contact with the first electronic component 111B. According to this configuration, the heat generated by the first electronic component 111B can be efficiently dissipated. Further, the protruding portion 12 may be configured to support the board 100, or may be configured to fix the board 100.

Although the embodiment of the present disclosure has been described above, it is needless to say that the technical scope of the present disclosure should not be construed as being limited by the description of the embodiment. It should be understood by those skilled in the art that the present embodiment is merely an example, and various modifications of the embodiment are possible within the scope of the invention described in the claims. The technical scope of the present disclosure should be determined based on the scope of the invention described in what is claimed is and the equivalent scope thereof.

What is claimed is:

1. An electronic device comprising:
a case;
a board provided in the case; and
a connector mounted on the board using an attachment pin,
wherein the case has a first portion and a second portion, the first portion facing the attachment pin and being made of resin, the second portion being different from the first portion and being made of metal.

2. The electronic device according to claim 1,
wherein a power conversion unit is mounted on the board.

3. The electronic device according to claim 1,
wherein the board includes a mounting surface on which the connector is mounted, and
wherein a back surface of the mounting surface of the board faces the case.
